(19) United States
(12) Patent Application Publication
(10) Pub. No.: US 2005/0099111 A1
(43) Pub. Date: May 12, 2005

(54) Method for the preparation of graphite nanofibers and emitter and display elements comprising the nanofibers

(76) Inventors: Masaaki Hirakawa, Ibaraki-ken (JP); Osamu Miura, Ibaraki-ken (JP); Hirohiko Murakami, Ibaraki-ken (JP); Kazunaga Ono, Ibaraki-ken (JP); Kenji Fujii, Saitama-ken (JP); Kensuke Okasaka, Saitama-ken (JP); Takaei Sasaki, Saitama-ken (JP)

Correspondence Address: ARENT FOX KINTNER PLOTKIN & KAHN, 1050 CONNECTICUT AVENUE, N.W., SUITE 400, WASHINGTON, DC, 20036, US

(21) Appl. No.: 10/663,838

(22) Filed: Sep. 17, 2003

(30) Foreign Application Priority Data
Sep. 17, 2002 (JP) 270104/2002

(51) Int. Cl. C23C 16/26

(52) U.S. Cl. 313/495; 427/249.6

(57) ABSTRACT

A method for preparing a graphite nanofiber is herein provided, which comprises a raw gases are supplied on the surface of a substrate provided thereon with a catalyst layer for the growth of graphite nanofibers according to the CVD technique, wherein the method is characterized by forming a catalyst layer having a desired thickness and then forming, on the catalyst layer of the substrate, a graphite nanofiber whose overall thickness is controlled and which comprises a graphite nanofiber layer and a non-fibrous layer. The resulting graphite nanofibers can be used in an emitter or a field emission display element. The thickness of the catalyst layer formed on a substrate is controlled by the method and this in turn permits the control of the thickness of the non-fibrous layer formed on the catalyst layer and the control of the thickness of the graphite nanofibers likewise formed on the catalyst layer.

### BACKGROUND OF THE INVENTION

The present invention relates to a method for the preparation of a graphite nanofiber as well as an emitter and a display element, which make use of the graphite nanofibers prepared according to the foregoing method. More specifically, the present invention pertains to a method for the preparation of a graphite nanofiber, which can control the overall film thickness by adjusting the film thickness of a catalyst layer formed on a substrate as well as an emitter and a display element, which make use of the graphite nanofibers prepared according to the foregoing method.

It has recently been expected that the graphite nanofibers may be used as a useful member for a variety of means such as an emitter, a means for storing hydrogen gas and a lithium (Li) ion battery.

As a conventional method for the preparation of a graphite nanofiber, there has been known, for instance, a technique comprising the step of reacting carbon monoxide gas or carbon dioxide gas with hydrogen gas (see, Japanese Un-Examined Patent Publication 2001-288625 (claim 6, the 6^{th} column on page 4).

However, when a graphite nanofiber is prepared according to the foregoing conventional technique using carbon monoxide gas and hydrogen gas, a curled nanofiber is formed. The shape of the curling (the curvature thereof or the degree of the bending) is not uniform and varies depending on individual fibers.

Moreover, the curled fiber is drawn towards electrodes due to the action of an electric field and accordingly, such a fiber may undergo a change in its shape. Due to such a phenomenon, when a graphite nanofiber is used in the emitter of an FED (Field Emission Display) having a triode structure, a short circuit may be formed between the emitter and the gate electrode. This short circuit greatly affects the quality of the product when preparing such FED since it may become a cause of the unevenness or irregularity of a light-emitting point. For this reason, there has been desired for the development of a method for preparing a graphite nanofiber, which does not form any short circuit even when it is used in an emitter.

### SUMMARY OF THE INVENTION

The present invention has been developed for the solution of the foregoing problems associated with the conventional method for the preparation of carbon nanofiber discussed above and accordingly, it is an object of the present invention to provide a method for the preparation of a carbon nanofiber, which never forms any short circuit even when used in, for instance, an emitter and which permits the elimination of the problem of the unevenness of a light-emitting point encountered when preparing an FED.

Another object of the present invention is to provide an emitter, which makes use of the carbon nanofiber prepared by the foregoing method.

A still another object of the present invention is to provide a display element, which makes use of the carbon nanofiber prepared by the foregoing method.

The inventors of this invention have conducted various studies to solve the foregoing problems associated with the conventional techniques for preparing a graphite nanofiber, have found that when controlling the overall film thickness by adjusting the film thickness of a catalyst layer formed on a substrate, a carbon nanofiber having desired properties can be obtained and have thus completed the present invention.

According to an aspect of the present invention, there is provided a method for the preparation of a graphite nanofiber comprising the steps of introducing raw gases on a substrate on which a catalyst layer for the growth of a graphite nanofiber has been formed and then forming a graphite nanofiber on the substrate according to a CVD method such as a thermal CVD method, the method being characterized by forming a catalyst layer having a desired thickness and then forming, on the catalyst layer of the substrate, a graphite nanofiber whose overall thickness is controlled and which comprises a graphite nanofiber layer and a non-fibrous layer, which is not a fiber.

The catalyst present in the catalyst layer for the growth of a graphite nanofiber deposited on a substrate is Fe, Co or an alloy containing at least one of these metals.

The raw gas is preferably a mixed gas comprising a carbon-supply gas such as acetylene, carbon monoxide or carbon dioxide and hydrogen gas.

The ratio of the carbon-supply gas in the foregoing mixed gas preferably ranges from 10 to 80% by volume. This is because if the ratio thereof is less than 10% by volume and it exceeds 80% by volume, the growth rate of the graphite nanofiber is considerably reduced.

The production of the foregoing graphite nanofiber is preferably carried out at a temperature ranging from 350 to 650° C. for 1 to 60 minutes. This is because if the temperature is less than 350° C., the growth rate of the graphite nanofiber is considerably reduced, while if it exceeds 650° C., the production cost of the nanofiber increases or the heat energy cost required for the production thereof is too high and the use of such a high temperature is inconvenient from the viewpoint of the industrial application of the method. In addition, if the time required for the production thereof is less than one minute, it is quite difficult to control the reaction or the growth of the nanofiber, while if it exceeds 60 minutes, the production cost is too high and it takes a quite long contact time.

Alternatively, it is also possible to carry out the method for preparing graphite nanofibers according to the present invention by forming lines consisting of the foregoing catalyst metal on the catalyst layer on a substrate such as a glass substrate or an Si wafer on which any graphite nanofiber cannot be formed according to any known method such as the sputtering method and then selectively forming graphite nanofibers only on the metal lines thus formed according to any CVD method such as the thermal CVD method.

According to another aspect of the present invention, there is provided an emitter, which comprises a carbon film formed on the surface of an electrode substrate or on the superficial patterned portions of a patterned electrode substrate, wherein the carbon film comprises the graphite nanofibers prepared according to the foregoing method.

According to a further aspect of the present invention, there is also provided a field emission display element, which comprises a cathode or an emitter prepared by providing graphite nanofibers formed according to the foregoing method on the superficial patterned portions of a patterned electrode substrate, and a anode, which comprises a phosphor and a transparent conductive film patterned in a desired shape and which is opposed to the graphite nanofibers and positioned at a desired distance from the nanofibers, wherein it is designed in such a manner that when an electric voltage is applied between a selected specific graphite nanofiber and the transparent conductive film, electrons are emitted from the specific graphite nanofiber to thus flash only a specific portion on the phosphor.

The present invention permits the control of the overall film thickness and the thickness of the non-fibrous layer by appropriately adjusting the film thickness of the catalyst layer for the growth of such a graphite nanofiber and accordingly, the present invention thus permits the production of a graphite nanofiber whose film thickness is controlled. According to the present invention, the film thickness of the graphite nanofiber can freely be controlled and therefore, the present invention permits the production of, for instance, a variety of emitters and display elements of various sizes depending on their film thickness. More specifically, an emitter whose height is controlled and a display element in which the height of the emitter portion is controlled can, for instance, be produced using graphite nanofibers whose overall film thickness is controlled and which can be prepared by changing the thickness of the catalyst layer to be formed, in advance, on the surface of a substrate. In the case of a field emission display element, an appropriate emitter-gate electrode distance can be ensured and therefore, this may lead to the solution of the problem of the unevenness of a light-emitting point of a display element.

### BRIEF DESCRIPTION OF THE DRAWINGS

FIG. 1 is an SEM micrograph of a graphite nanofiber whose catalyst layer is thin on the order of 10 nm and which is prepared according to the method of the present invention.

FIG. 2 is an SEM micrograph of a graphite nanofiber whose catalyst layer is thick on the order of 50 nm and which is prepared according to the method of the present invention.

### DESCRIPTION OF THE PREFERRED EMBODIMENTS

Embodiments of the present invention will now be described in more detail with reference to the accompanying drawings.

According to the present invention, a graphite nanofiber may, for instance, be prepared by placing a substrate provided thereon with a catalyst layer formed by depositing, on the surface thereof, Fe, Co or an alloy comprising at least one of these metals in a thermal CVD equipment equipped with an electric furnace; holding a reduced pressure condition within the equipment; introducing raw gases or a mixture of hydrogen gas and a carbon-supply gas consisting of a carbon-containing gas such as carbon monoxide or carbon dioxide into the CVD equipment to a total pressure in the equipment preferably ranging from 6500 to 133000 Pa (50 to 1000 Torr); and then growing a layer comprising graphite nanofibers on the surface of the substrate at a film-forming temperature on the order of not more than that against which the substrate can proof (hereunder referred to as “heat-resistant temperature of the substrate”) and preferably ranging from 350 to 650° C. for a desired time. In this connection, if the pressure within the equipment is less than 6500 Pa, any growth of a graphite nanofiber is not observed, while if it exceeds 133000 Pa, the cost required for the assembly of the equipment increases.

The product obtained by depositing graphite nanofibers on a substrate according to the foregoing procedures may serve as an emitter. In addition, when the resulting graphite nanofiber is used in a display, it is necessary to grow graphite nanofibers at a temperature less than the heat-resistant temperature of a substrate such as a glass substrate.

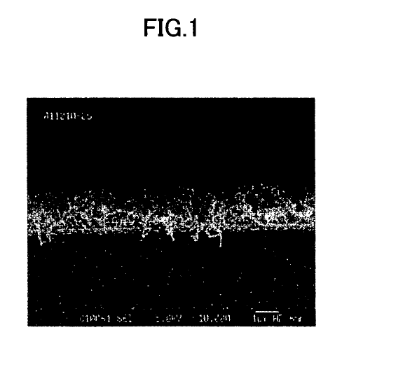

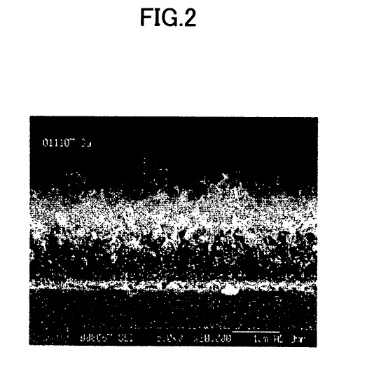

The graphite nanofiber grown on the surface of a substrate comprises, as will be seen from FIGS. 1 and 2, non-fibrous layer formed on the catalyst layer having a desired thickness and a graphite nanofiber layer formed on the non-fibrous layer. In this respect, if the thickness of the catalyst layer is thin (less than 20 nm), any non-fibrous layer is not formed and only a graphite nanofiber layer is formed on the substrate.

The field electron emission characteristics of a carbon-containing emitter can considerably be improved by forming graphite nanofibers such as those discussed above on the surface of a substrate through the film formation on the substrate on which catalyst layers are formed. More specifically, the carbon-containing emitter prepared by the method of the present invention permits the electron emission at a current density higher than that observed for the conventional carbon nanotubes even at an applied electric voltage identical to that used in the latter and the emitter would permit the achievement of electron emission at such a sufficiently high current density that it can be used as an electron source for CRT.

In the present invention, the carbon film constituting an emitter is formed on the surface of a cathode substrate. In the case of a carbon film formed on the patterned portions on the surface of a patterned cathode substrate, a desired pattern can be formed on the surface of a cathode substrate according to, for instance, the known lithography technique in which any known light-sensitive resin is applied onto the surface of the substrate, followed by exposing the resin layer to light through a mask carrying a desired pattern and then removing the exposed portion of the resin layer; or the printing technique to thus obtain a cathode substrate having such a desired pattern on the surface, followed by the growth of graphite nanofibers on the specific pattern on the substrate according to the foregoing method to thus form a carbon film in a desired pattern. The resulting product can be used as an emitter.

The graphite nanofibers formed on the surface of a substrate can be collected and recovered to thus obtain powdery graphite nanofibers. This powder is dispersed in, for instance, a conductive paste such as a silver paste to give a graphite nanofiber-containing paste, the resulting paste is applied onto an electrode substrate and then dried to thus adhere the graphite nanofiber to desired positions on the electrode substrate; or the powder is dispersed in any known conductive solvent to give a graphite nanofiber-containing dispersion and then the graphite nanofiber is adhered to desired positions on an electrode substrate according to the electro-deposition technique while the electrode substrate is immersed in the resulting dispersion, to thus produce a cold cathode source or an emitter. As has been described above, if the graphite nanofiber is handled in the form of a powdery product, an emitter (a cold cathode source) having a variety of desired patterns depending on the purposes can thus easily be prepared, according to, for instance, a printing method or an electro-deposition method.

The display element according to the present invention is field emission one and is provided with an emitter having a carbon film, which has a desired pattern and consists of the graphite nanofiber. Accordingly, a phosphor can be combined with a transparent conductive film patterned in a desired shape to thus flash only specific portions on the phosphor depending on various purposes.

This field emission display element may be prepared according to, for instance, the following process. First, a cathode serving as a field emission electron source consisting of the foregoing graphite nanofibers is formed on a cathode substrate and a anode is formed on a anode substrate. The cathode and anode are fixed in such a manner that they are opposed to one another while keeping a desired distance between the cathode and anode, the surroundings of these cathode and anode are sealed while maintaining a high vacuum within the space defined by these electrodes and finally the exhaust port is sealed to thus give a display element.

Regarding the resulting display element, a field emission type cathode is formed on the surface of the cathode substrate on the side of the anode substrate, while a layer of a conductive material for forming a anode, which is covered with a phosphor, is formed on the surface of the anode substrate on the side of the cathode substrate and serves as a anode or a luminous or display portion. The layer of a conductive material for a anode may be formed from, for instance, Al, Ag, Cu, Au, Nb, Ta, Mo, W, In and Sn. An insulator consisting of, for instance, SiN, TiO₂ or SiON may be formed between the anode substrate and the conductive material for the anode. The shielding film may serve to isolate any gas possibly generated from the anode substrate and thus protect the internal atmosphere of the assembly from any deterioration.

A cathode conductor is formed on the inner surface of the cathode substrate, an insulator is formed on the cathode conductor and a gate electrode is formed on this insulator. A hole is formed through the insulator and the gate electrode and an emitter consisting of a graphite nanofiber is formed on the cathode conductor thus exposed within the hole.

The present invention will hereunder be described in more detail with reference to the following Examples, but the present invention is not restricted to these specific Examples at all.

### EXAMPLE 1

A catalyst layer having a thickness of 5, 10, 20, 25 or 50 nm was formed on the surface of a glass substrate according to the sputtering method using Inver 42 as a catalyst. Each of these substrates provided thereon with such a catalyst layer was introduced into a thermal CVD equipment and then the equipment was evacuated to a pressure of 1 Pa. Thereafter, a process gas comprising 50/50 (% by volume) mixture of CO and H₂ gases was introduced into the equipment up to the atmospheric pressure. The substrate was heated up to 550° C. and the raw gases were reacted for 15 minutes while maintaining the system at that temperature to thus form a graphite nanofiber (GNF) having a diameter of about 50 nm and a length of 1 μm.

This graphite nanofiber sample was inspected for the correlation between the thickness of the catalyst layer and that of the non-fibrous (NF) layer or the GNF, which were determined from the cross sectional micrograph obtained in the scanning electron microscopic observation. The results thus obtained are listed in the following Table 1. In Table 1, the ratio (%) of the surface area on the substrate occupied by the NF layer is calculated according to the following relation: {(the thickness of the NF layer)/(the thickness of the NF layer+the thickness of the GNF layer)}×100.

TABLE 1

| | | | | | |
|---|---|---|---|---|---|
| Thickness of Catalyst Layer (nm) | 5 | 10 | 20 | 25 | 50 |
| Thickness of NF Layer (nm) | 0 | 0 | 150 | 200 | 1000 |
| Thickness of GNF Layer (nm) | 1500 | 1500 | 1200 | 1200 | 1000 |
| Ratio of NF Layer (%) | 0 | 0 | 11 | 14 | 50 |

FIG. 1 is an SEM cross sectional micrograph of a sample having a thin catalyst layer on the order of 10 nm and FIG. 2 is an SEM cross sectional micrograph of a sample having a thick catalyst layer on the order of 50 nm, among the samples listed in Table 1. The results shown in these FIGS. 1 and 2 clearly indicate that when the catalyst layer is thin (FIG. 1), any non-fibrous layer is not observed and that when the catalyst layer is thick (FIG. 2), there is observed the formation of a catalyst layer in a thickness of about 1 μm. The results listed in Table 1 and depicted on FIGS. 1 and 2 clearly indicate that when the catalyst layer is thin, the non-fibrous layer formed is also thin.

### EXAMPLE 2

In this Example, an emitter consisting of the graphite nanofiber prepared in Example 1 was inspected for various properties. As a result, it was confirmed that the emitter initiated the electron emission when the applied voltage reached 0.8 V/μm, that thereafter the quantity of emitted electrons increased as the applied voltage was raised and that the quantity of emitted electrons reached 10 mA/cm² at an applied voltage of 5 V/μm. In this respect, the quantity of emitted electrons observed for a needle-like emitter prepared according to a conventional technique using carbon nanotubes was found to be only 1 mA/cm² at an applied voltage of 3 V/Im. Contrary to this, the emitter according to the present invention can provide a large quantity of emitted electrons at a very low applied voltage as has been discussed above.

### EXAMPLE 3

An Fe film was formed or deposited on a glass substrate according to the sputtering technique, lines of the Fe film were formed according to, for instance, the photolithography technique and gate electrodes were then formed on these Fe lines through glass ribs. The substrate provided thereon with the gate electrodes thus formed was placed in the same thermal CVD equipment used in Example 1 and then the pressure within the equipment was reduced to 1 Pa. Then a process gas comprising hydrogen gas and carbon dioxide gas was introduced into the equipment, while the gas was flown through the equipment at a pressure of 0.10 MPa (1 atm), the temperature of the substrate was heated up to 550° C. using an electric furnace, the raw gases were reacted at this temperature for 10 minutes and as a result, it was found that graphite nanofibers grew on the Fe lines visible on the surface of the substrate as observed in Example 1.

The surroundings of the cathode substrate on which the graphite nanofibers had grown and the anode substrate carrying lines of a phosphor thereon were sealed, while the interior thereof was maintained at a vacuum to thus give a display element. In this respect, it was confirmed that when an electric voltage of 100 V was applied to the gate electrodes while applying an electric voltage on the order of several kV to the anode, electron could be emitted from an arbitrary dot.

In the foregoing Example, graphite nanofibers were grown while the pressure in the equipment was maintained at 0.10 MPa (1 atm), but the graphite nanofiber can suitably be grown if the pressure in the equipment ranges from 6500 to 133000 Pa.

As has been described above in detail, the thickness of the catalyst layer formed on a substrate is controlled according to the present invention and this in turn permits the control of the thickness of the non-fibrous layer formed on the catalyst layer and the control of the thickness of the graphite nanofibers likewise formed on the catalyst layer. Since the present invention thus permits the preparation of a graphite nanofiber layer whose overall thickness is controlled, the substrate provided thereon with the graphite nanofiber layer can solve the problem such that when it is used as, for instance, an FED emitter having a triode structure, the emitter is attracted by the gate electrode and thus forms a short circuit with the gate electrode and the use thereof may thus permits the solution of the problem of the unevenness of the light-emitting point in FED.

Moreover, the use of the foregoing graphite nanofiber likewise permits the production and supply of a carbon-containing emitter (cold cathode source) capable of accomplishing a high electron emission density and low field electron emission characteristics, which have never been achieved by the conventional carbon nanotubes.

Further, it is possible to provide a display element which permits the light-emission at an arbitrary portion on the layer of a phosphor through the use of such an emitter.

1. A method for preparing a graphite nanofiber, which comprises a raw gases are supplied on the surface of a substrate provided thereon with a catalyst layer for the growth of graphite nanofibers according to the CVD technique, wherein the method is characterized by forming a catalyst layer having a desired thickness and then forming, on the catalyst layer of the substrate, a graphite nanofiber whose overall thickness is controlled and which comprises a graphite nanofiber layer and a non-fibrous layer.

2. The method for preparing a graphite nanofiber as set forth in claim 1, wherein the catalyst present in the catalyst layer for the growth of a graphite nanofiber deposited on a substrate is Fe, Co or an alloy containing at least one of these metals.

3. The method for preparing a graphite nanofiber as set forth in claim 1, wherein the raw gas is a mixed gas comprising acetylene, carbon monoxide or carbon dioxide as a carbon-supply gas and hydrogen gas.

4. The method for preparing a graphite nanofiber as set forth in claim 3, wherein the ratio of the carbon-supply gas in the mixed raw gas ranges from 10 to 80% by volume.

5. The method for preparing a graphite nanofiber as set forth in claim 1, wherein the graphite nanofiber is prepared at a temperature ranging from 350 to 650° C.

6. The method for preparing a graphite nanofiber as set forth in claim 1, wherein the preparation of the graphite nanofiber is carried out for 1 to 60 minutes.

7. The method for preparing a graphite nanofiber as set forth in claim 1, wherein the method is carried out by forming lines consisting of the foregoing catalyst metal on the catalyst layer on a substrate on which any graphite nanofiber cannot be formed and then selectively forming graphite nanofibers only on the metal lines thus formed according to the CVD method.

8. The method for preparing a graphite nanofiber as set forth in claim 7, wherein the substrate is a glass substrate or an Si wafer.

9. An emitter, which comprises a carbon film provided on the surface of an electrode substrate or a patterned portion on the surface of a patterned electrode substrate, wherein the carbon film is one comprising the graphite nanofiber prepared according to the method as set forth in any one of claims 1 to 8.

10. A field emission display element, which comprises a cathode or an emitter prepared by providing graphite nanofibers formed according to the method as set forth in any one of claims 1 to 8 on the superficial patterned portions of a patterned electrode substrate, and a anode, which comprises a phosphor and a transparent conductive film patterned into a desired shape and which is opposed to the graphite nanofibers and positioned at a desired distance from the nanofibers, wherein it is designed in such a manner that when applying an electric voltage between a selected specific graphite nanofiber and the transparent conductive film electrons are emitted from the specific graphite nanofiber to thus flash only a specific portion on the phosphor.
